(19) United States
(12) Patent Application Publication
(10) Pub. No.: US 2022/0255523 A1
(43) Pub. Date: Aug. 11, 2022

(54) DYNAMIC AUDIO BROADCASTING METHOD AND AUDIO BROADCASTING APPARATUS

(71) Applicant: QISDA CORPORATION, Taoyuan City (TW)

(72) Inventor: Wu-Chi Chu, Taoyuan City (TW)

(73) Assignee: QISDA CORPORATION, Taoyuan City (TW)

(21) Appl. No.: 17/465,817

(22) Filed: Sep. 2, 2021

(30) Foreign Application Priority Data
Feb. 8, 2021 (CN) 202110171009.9

(51) Int. Cl. H03G 3/32; H04R 3/00; H03G 3/30; H03F 3/183

(52) U.S. Cl. CPC H03G 3/32; H04R 3/00; H03F 2200/03; H03F 3/183; H04R 2430/01; H03G 3/3005

(57) ABSTRACT

A dynamic audio broadcasting method is to receive an audio signal and an ambient sound, compare the audio signal and the ambient sound to adjust an amplification volume of the audio signal, and play the audio signal at the amplification volume. An audio broadcasting apparatus includes an audio receiver, an ambient sound receiver, a speaker, and a processing module electrically connected to the above components. The processing module is configured to receive an audio signal and an ambient sound through the audio receiver and the ambient sound receiver respectively, compare the audio signal and the ambient sound to adjust an amplification volume of the audio signal, and play the audio signal at the amplification volume through the speaker.

### BACKGROUND OF THE INVENTION

### 1. Field of the Invention

The present invention relates to a broadcasting method, and more particularly to a broadcasting method capable of dynamically adjusting the playback volume and an audio broadcasting apparatus using the broadcasting method.

### 2. Description of the Prior Art

In long-distance voice communication, the local listener will hear the local ambient sound and the sound played at the local end by the audio signal from the remote end at the same time. Therefore, the volume level of the ambient sound will significantly affect whether the listener can clearly hear the sound played at the local end. When the ambient sound is louder, the listener can increase the volume for playing the audio signal at the local end by himself/herself, so as to heard the played sound clearly. Similarly, when the ambient sound is lower, the listener can decrease the volume for playing the audio signal at the local end by himself/herself, so as to reduce harshness. However, in fact, the ambient sound may vary from time to time. For example, in a moving vehicle, the ambient sound received by the listener may vary from time to time due to different road conditions. It is impractical to request the listener to immediately adjust the volume for playing the audio signal according to the volume of the ambient sound.

### SUMMARY OF THE INVENTION

An objective of the invention is to provide a dynamic audio broadcasting method, which can dynamically adjust the volume for playing an audio signal in consideration of the volume of an actual ambient sound.

A dynamic audio broadcasting method according to the present invention includes the following steps: (a) receiving an audio signal and an ambient sound; (b) measuring a first amplification volume of the audio signal and an ambient sound volume of the ambient sound; (c) adjusting the first amplification volume to a second amplification volume according to the first amplification volume and the ambient sound volume; and (d) playing the audio signal at the second amplification volume. Thereby, the playback of the audio signal will take the ambient sound into consideration, so as to reduce the influence of the ambient sound on the listener's listening.

Another objective of the invention is to provide an audio broadcasting apparatus, which can dynamically adjust the volume for playing an audio signal in consideration of the volume of an actual ambient sound.

An audio broadcasting apparatus according to the present invention includes an audio receiver, an ambient sound receiver, a speaker, and a processing module. The processing module is electrically connected to the audio receiver, the ambient sound receiver, and the speaker. The processing module receives an audio signal and an ambient sound through the audio receiver and the ambient sound receiver respectively, measures a first amplification volume of the audio signal and an ambient sound volume of the ambient sound, adjusts the first amplification volume to a second amplification volume according to the first amplification volume and the ambient sound volume, and plays the audio signal through the speaker at the second amplification volume. Thereby, the processing module will take the ambient sound into consideration when playing the audio signal, so as to reduce the influence of the ambient sound on the listener's listening.

Compared with the prior art, the dynamic audio broadcasting method and the audio broadcasting apparatus can automatically and continuously adjust the playback volume of the audio signal according to the received audio signal and ambient sound, which can solve the problem in the prior art that it is difficult for the listener to adjust the playback volume in real time to reduce the influence of the ambient sound on the listener's listening.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a flowchart of a dynamic audio broadcasting method according to a first embodiment.

FIG. 2 is a flowchart of a dynamic audio broadcasting method according to a second embodiment.

FIG. 3 is a functional block diagram of an audio broadcasting apparatus according to a third embodiment.

### DETAILED DESCRIPTION

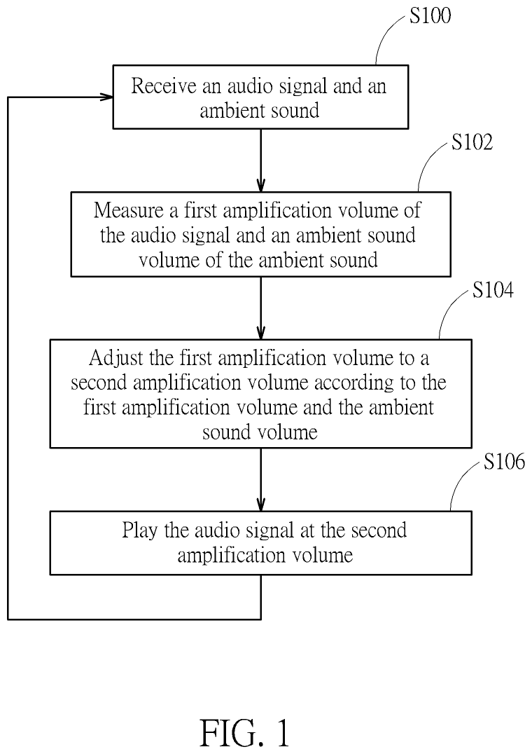

Please refer to FIG. 1. A dynamic audio broadcasting method according to a first embodiment can adjust the playback volume in consideration of a playing environment, so as to reduce the influence of the environment on listeners' listening. Therein, as shown by the step S100, the dynamic audio broadcasting method is to receive an audio signal and an ambient sound. Then, as shown by the step S102, the dynamic audio broadcasting method is to measure a first amplification volume of the audio signal and an ambient sound volume of the ambient sound. The dynamic audio broadcasting method is to adjust the first amplification volume to a second amplification volume according to the first amplification volume and the ambient sound volume, as shown by the step S104. The dynamic audio broadcasting method is to play the audio signal at the second amplification volume, as shown by the step S106. Afterwards, the dynamic audio broadcasting method returns to the step S100. Thereby, the dynamic audio broadcasting method can be set to be executed automatically and continuously (for example, executed periodically for streaming audio). The dynamic audio broadcasting method can adjust the playback volume according to the audio signal and ambient sound (which are received, for example but not limited to, at the same time), so that the played sound can be heard clearly by the listener in the ambient sound or the degree of the listener recognizing the played sound can be improved at least.

In practice, the adjusted amplification volume (i.e. the second amplification volume) is greater than the volume of the ambient sound volume, so that the listener can hear the played sound clearly. For example, the second amplification volume can be set to be greater than the ambient sound volume by a certain volume (or an adjustment degree), for example but not limited to between 5 decibels and 15 decibels, by which the listener can effectively hear the played sound clearly. In practice, the adjustment degree can be set by users (or listeners). For example, the dynamic audio broadcasting method provides a user-settable adjustment degree. The user-settable adjustment degree includes a first amplitude modulation and a second amplitude modulation (or more amplitude modulations) for users to choose; therein, the first amplitude modulation is greater than the second amplitude modulation. Thereby, in the step S104, the first amplification volume is adjusted to the second amplification volume according to the user-settable adjustment degree (or the first amplitude modulation or the second amplitude modulation chosen by the user). In addition, in practice, the second amplification volume can be less than the ambient sound volume. Because the second amplification volume is closer to the ambient sound volume (relative to the difference between the first amplification volume and the ambient sound volume), the adjustment can improve the degree of the listener recognizing the played sound and also help the listener to hear the played sound clearly.

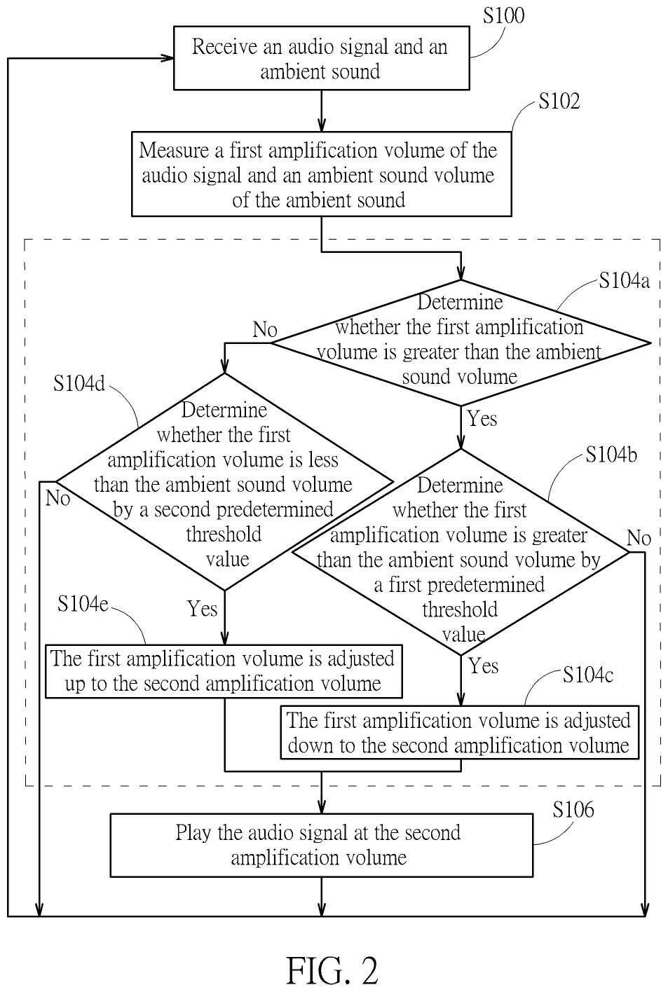

Furthermore, in the first embodiment, in the step S104, the adjustment to the amplification volume (i.e. adjusting the first amplification volume to the second amplification volume) can be carried out based on the difference between the first amplification volume and the ambient sound volume. As shown by FIG. 2, a dynamic audio broadcasting method according to a second embodiment is similar to the dynamic audio broadcasting method according to the first embodiment. After the steps S100 and S102, the dynamic audio broadcasting method according to the second embodiment is to determine whether the first amplification volume is greater than the ambient sound volume, as shown by the step S104a. If YES, the step S104b is to be executed; if NO, the step S104b is to be executed. In the step S104b, the dynamic audio broadcasting method is to determine whether the first amplification volume is greater than the ambient sound volume by a first predetermined threshold value. If YES, the first amplification volume is adjusted down to the second amplification volume, as shown by the step S104c. In the step S104d, the dynamic audio broadcasting method is to determine whether the first amplification volume is less than the ambient sound volume by a second predetermined threshold value. If YES, the first amplification volume is adjusted up to the second amplification volume, as shown by the step S104e. Then, as shown by the step S106, the dynamic audio broadcasting method is to play the audio signal at the second amplification volume (which is obtained by adjusting the first amplification volume according to the step S104c or S104e).

In other words, if the first amplification volume is greater than the ambient sound volume by the first predetermined threshold value, the second amplification volume is less than the first amplification volume; if the first amplification volume is less than the ambient sound volume by the second predetermined threshold value, the second amplification volume is greater than the first amplification volume. Thereby, the adjustment to the amplification volume is not executed until the difference between the first amplification volume and the ambient sound volume reaches a certain level, which can reduce the hardware burden of executing the dynamic audio broadcasting method and also can prevent the amplification volume from being adjusted too frequently and making the played sound lifeless (e.g. the ups and downs of the sound). Furthermore, the dynamic audio broadcasting method can prevent the played sound (by playing the audio signal at the second amplification volume) from being too large and harsh, causing a burden on the listener's ears. In practice, the first predetermined threshold value and the second predetermined threshold value are not limited to the same, and can be set to, for example but not limited to, 5, 10, or 15 decibels. In practice, the first predetermined threshold value and the second predetermined threshold value can be set by users. For example, the dynamic audio broadcasting method provides a plurality of setting values for listeners to set.

Furthermore, in principle, that the second amplification volume (obtained by adjusting the first amplification volume according to the step S104c or S104e) is greater than the ambient sound volume allows the listener to hear the played sound clearly; however, it is not limited thereto in practice. For example, if the first amplification volume is less than the ambient sound volume, the first amplification volume can be adjusted up to the second amplification volume which is less than the ambient sound volume. The second amplification volume is closer to the ambient sound volume (relative to the difference between the first amplification volume and the ambient sound volume), so the adjustment can improve the degree of the listener recognizing the played sound and also help the listener to hear the played sound clearly. In addition, same as the dynamic audio broadcasting method of the first embodiment, the dynamic audio broadcasting method of the second embodiment can set the second amplification volume to be greater than the ambient sound volume by a certain volume (or an adjustment degree), for example but not limited to between 5 decibels and 15 decibels, by which the listener can effectively hear the played sound clearly. For other descriptions about the adjustment degree, please refer to the relevant descriptions in the foregoing, which will not be repeated in addition.

In the above embodiments, the dynamic audio broadcasting method can be executed on an audio broadcasting apparatus disposed in a space (e.g. vehicle cockpits, rooms near traffic arteries, noisy offices, and so on). There is ambient sound (for example, in the vehicle cockpit, echoes from the road when the vehicle is moving, the sound produced by the vehicle engine in operation, the sound from the outside of the vehicle, etc.) spreading in the space. The sound played by the audio broadcasting apparatus according to the dynamic audio broadcasting method can be heard clearly by listeners (such as drivers or passengers) in this space, or the degree of the listener recognizing the played sound can be improved at least. The source of the audio signal depends on actual applications of the dynamic audio broadcasting method. For example, the source of the audio signal can be a remote mobile device (e.g. a mobile phone of a caller) in a mobile communication connection. For another example, the source of the audio signal can be a device capable of short-distance communication (e.g. a mobile phone, a tablet, etc.).

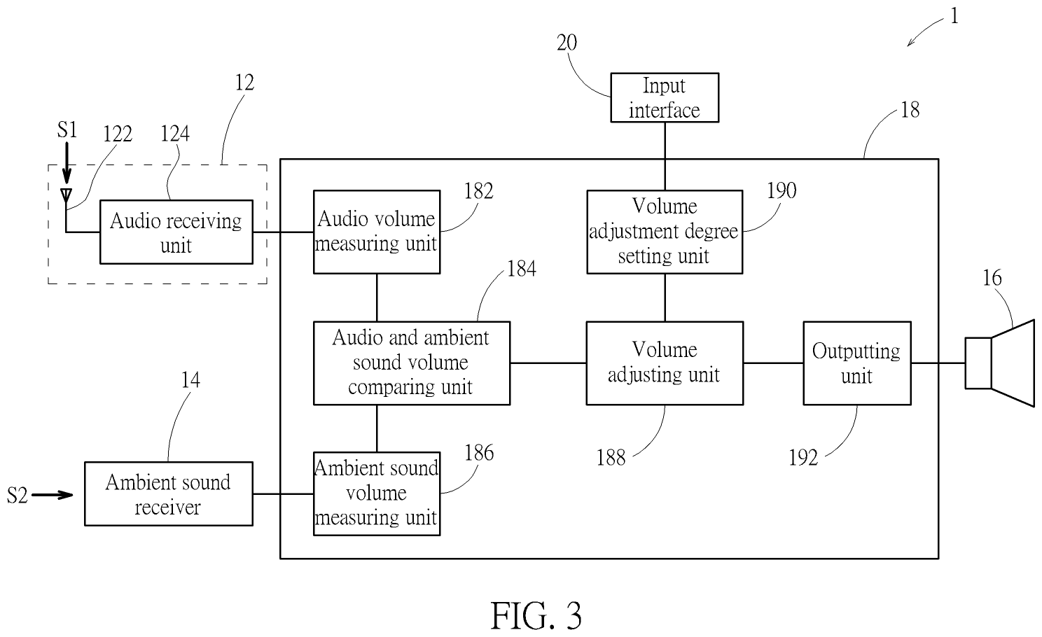

As shown by FIG. 3, an audio broadcasting apparatus 1 according to a third embodiment includes an audio receiver 12, an ambient sound receiver 14, a speaker 16, and a processing module 18. The processing module 18 is electrically connected to the audio receiver 12, the ambient sound receiver 14, and the speaker 16. In practice, the audio broadcasting apparatus 1 can be but not limited to be integrated into a vehicle control system (including a vehicle computer, a sound system, etc.). Therein, the audio receiver 12 can include an antenna 122 (for receiving wireless signals, e.g. radio broadcast signals, mobile communication signals, wifi signals, Bluetooth signals, etc.) and an audio receiving unit 124 (and a connection port capable of transmitting audio signals, e.g. USB). The ambient sound receiver 14 can include a microphone of the sound system (which can be disposed on but not limited to a steering wheel). The speaker 16 can include a speaker of the sound system. In practice, the processing module 18 can achieved by one or more circuit board modules (each of which includes a circuit board and a processor, memory, and other required electronic components on the circuit board), or by a control module of the vehicle computer or sound system). The processing module 18 includes, for example but not limited to, an audio volume measuring unit 182, an audio and ambient sound volume comparing unit 184, an ambient sound volume measuring unit 186, a volume adjusting unit 188, a volume adjustment degree setting unit 190, and an outputting unit 192.

In the third embodiment, the audio broadcasting apparatus 1 can execute the dynamic audio broadcasting methods in the first and second embodiments. The above description of the dynamic audio broadcasting methods and variations thereof is also applicable here, and will not be repeated in addition. In short, the processing module 18 receives an audio signal S1 and an ambient sound S2 through the audio receiver 12 and the ambient sound receiver 14 respectively (as shown by the step S100); therein, the audio receiver 12 uses the audio receiving unit 124 to receive the audio signal S1 through the antenna 122. The processing module 18 measures a first amplification volume of the audio signal S1 and a ambient sound volume of the ambient sound S2 (as shown by the step S102); therein, the processing module 18 uses the audio volume measuring unit 182 to measure the audio signal S1 so as to obtain the first amplification volume, and uses the ambient sound volume measuring unit 186 to measure the ambient sound S2 so as to obtain the ambient sound volume. The processing module 18 adjusts the first amplification volume to a second amplification volume according to the first amplification volume and the ambient sound volume (as shown by the step S104); therein, the processing module 18 uses the audio and ambient sound volume comparing unit 184 to compare the first amplification volume with the ambient sound volume, and accordingly uses the volume adjusting unit 188 to adjust the first amplification volume to the second amplification volume. The processing module 18 plays the audio signal S1 through the speaker 16 at the second amplification volume (as shown by the step S106); therein, the processing module 18 uses the outputting unit 192 to play the audio signal S1 through the speaker 16 at the second amplification volume.

In an application, if the processing module 18 determines that the first amplification volume is greater than the ambient sound volume by a first predetermined threshold value, the second amplification volume is less than the first amplification volume (as shown by the steps S104a, S104b, S104c). Furthermore, if the processing module 18 determines that the first amplification volume is less than the ambient sound volume by a second predetermined threshold value, the second amplification volume is greater than the first amplification volume (as shown by the steps S104a, S104d, S104e).

In another application, the processing module 18 can store a user-settable adjustment degree (stored in the volume adjustment degree setting unit 190). The processing module 18 adjusts the first amplification volume to the second amplification volume according to the user-settable adjustment degree. The user-settable adjustment degree includes a first amplitude modulation and a second amplitude modulation (or more amplitude modulations) for users to choose (e.g. through an input interface 20, which includes a plurality of keyswitches, a touch screen, etc.).

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A dynamic audio broadcasting method, comprising the following steps:
(a) receiving an audio signal and an ambient sound;
(b) measuring a first amplification volume of the audio signal and an ambient sound volume of the ambient sound;
(c) adjusting the first amplification volume to a second amplification volume according to the first amplification volume and the ambient sound volume; and
(d) playing the audio signal at the second amplification volume.

2. The dynamic audio broadcasting method according to claim 1, wherein in the step (c), if the first amplification volume is greater than the ambient sound volume by a first predetermined threshold value, the second amplification volume is less than the first amplification volume.

3. The dynamic audio broadcasting method according to claim 1, wherein in the step (c), if the first amplification volume is less than the ambient sound volume by a second predetermined threshold value, the second amplification volume is greater than the first amplification volume.

4. The dynamic audio broadcasting method according to claim 1, wherein the second amplification volume is greater than the ambient sound volume.

5. The dynamic audio broadcasting method according to claim 4, wherein the second amplification volume is greater than the ambient sound volume by 5 decibels to 15 decibels.

6. The dynamic audio broadcasting method according to claim 1, wherein in the step (c), the first amplification volume is adjusted to the second amplification volume according to a user-settable adjustment degree.

7. The dynamic audio broadcasting method according to claim 6, wherein the user-settable adjustment degree comprises a first amplitude modulation and a second amplitude modulation, the first amplitude modulation is greater than the second amplitude modulation.

8. An audio broadcasting apparatus, comprising:
an audio receiver;
an ambient sound receiver;
a speaker; and
a processing module, electrically connected to the audio receiver, the ambient sound receiver, and the speaker, the processing module receiving an audio signal and an ambient sound through the audio receiver and the ambient sound receiver respectively, measuring a first amplification volume of the audio signal and an ambient sound volume of the ambient sound, adjusting the first amplification volume to a second amplification volume according to the first amplification volume and the ambient sound volume, and playing the audio signal through the speaker at the second amplification volume.

9. The audio broadcasting apparatus according to claim 8, wherein if the processing module determines that the first amplification volume is greater than the ambient sound volume by a first predetermined threshold value, the second amplification volume is less than the first amplification volume.

10. The audio broadcasting apparatus according to claim 8, wherein if the processing module determines that the first amplification volume is less than the ambient sound volume by a second predetermined threshold value, the second amplification volume is greater than the first amplification volume.

11. The audio broadcasting apparatus according to claim 8, wherein the second amplification volume is greater than the ambient sound volume.

12. The audio broadcasting apparatus according to claim 8, wherein the processing module adjusts the first amplification volume to the second amplification volume according to a user-settable adjustment degree.
